(19) United States
(12) Patent Application Publication
(10) Pub. No.: US 2006/0154433 A1
(43) Pub. Date: Jul. 13, 2006

(54) Semiconductor device having MIM element

(75) Inventor: Michihiro Onoda, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/131,417

(22) Filed: May 18, 2005

(30) Foreign Application Priority Data
Jan. 7, 2005 (JP) 2005-002722

(51) Int. Cl. H01L 21/20; H01L 21/8242

(52) U.S. Cl. 438/393; 438/250; 438/381

(57) ABSTRACT

A semiconductor device having: a semiconductor substrate; a plurality of semiconductor elements formed in the semiconductor substrate; a metal wiring made of a first metal layer and formed above the semiconductor substrate; a lower electrode made of the first metal layer and formed above the semiconductor substrate; a dielectric film formed on the lower electrode in a shape withdrawing from a periphery of the lower electrode; and an upper electrode formed on the dielectric film in a shape withdrawing from a periphery of the dielectric film, wherein the lower electrode, the dielectric film and the upper electrode form a MIM capacitor element. There are provided a semiconductor device having a MIM capacitor element capable of suppressing leak current as much as possible, and its manufacture method.

### CROSS REFERENCE TO RELATED APPLICATION

This application is based on and claims priority of Japanese Patent Application No. 2005-002722 filed on Jan. 7, 2005, the entire contents of which are incorporated herein by reference.

### BACKGROUND OF THE INVENTION

A) Field of the Invention

The present invention relates to a semiconductor device and its manufacture method, and more particularly to a semiconductor device having a high precision MIM capacitor element and its manufacture method.

B) Description of the Related Art

Analog circuits require high precise and large capacitance elements. Conventionally known capacitor elements include a capacitor element having the structure of a silicon substrate—a gate insulating film—a polysilicon film similar to the insulated gate structure, and a capacitor having the structure of a polysilicon film—an insulating film—a polysilicon film (PIP) having another polysilicon film in addition to a gate electrode polysilicon film. Using semiconductor as the electrode of a capacitor is not suitable for a high precision capacitor element because of some problems that semiconductor has a resistance higher than that of metal and a depletion layer is formed depending upon the conductivity type of semiconductor and the polarity of applied voltage, resulting in a change in capacitance.

These problems can be solved by a metal film—an insulating film—a metal film (MIM) capacitor element which uses metal instead of semiconductor and is highly precise. A conductive metal nitride film is also called a metal film in this specification. Even a MIM capacitor element cannot satisfy the requirements of high precision if there is leak between electrodes.

Using the manufacture processes for a MIM capacitor element common to the manufacture processes for other structures of a semiconductor device is desired from the viewpoint of manufacture yield improvements and cost reduction due to a reduction in the number of processes. A lower electrode is formed at the same time when an aluminum wiring is formed. In this case, it is desired to pattern an upper electrode layer by a process different from a process of patterning the lower electrode and wiring layers, and not to leave a metal layer for the upper electrode layer on the wiring. The upper electrode layer and a dielectric film are patterned by the same process. In MIM capacitor elements manufactured by these processes, it is known that leak current is likely to flow, particularly when an SiON antireflection film is formed after the upper electrode and dielectric film are patterned.

Japanese Patent Laid-open Publication No.2002-353328 proposes the processes of patterning an upper electrode and a dielectric film, thereafter depositing an insulating film to form side wall spacers by anisotropic etching, and then forming an antireflection film. It is described that leak current is suppressed by disposing the antireflection film away from the dielectric film.

Japanese Patent Laid-open Publication No. 2003-318269 describes that leak current cannot be suppressed perfectly because even if side wall spacers are formed, minute leak current flows in the region where the side wall spacers are not formed. In order to suppress this minute leak current, this Publication proposes to interpose an insulating film between the upper electrode and antireflection film, as a leak guard.

### SUMMARY OF THE INVENTION

An object of this invention is to provide a semiconductor device having a MIM capacitor element capable of suppressing leak current as much as possible and its manufacture method.

Another object of this invention is to provide a semiconductor device having a MIM capacitor element having the structure capable of suppressing leak current as verified by experiments made by the present inventor, and its manufacture method.

According to one aspect of the present invention, there is provided a semiconductor device comprising:

a semiconductor substrate;

a plurality of semiconductor elements formed in the semiconductor substrate;

a metal wiring made of a first metal layer and formed above the semiconductor substrate;

a lower electrode made of the first metal layer and formed above the semiconductor substrate;

a dielectric film formed on the lower electrode in a shape withdrawing from a periphery of the lower electrode; and

an upper electrode formed on the dielectric film in a shape withdrawing from a periphery of the dielectric film,

wherein the lower electrode, the dielectric film and the upper electrode form a MIM capacitor element.

According to another aspect of the present invention, there is provided a semiconductor device manufacture method comprising steps of:

(a) forming a plurality of semiconductor elements in a semiconductor substrate;

(b) forming a first metal layer, a dielectric film and a second metal layer above the semiconductor substrate;

(c) patterning the second metal layer to leave an upper electrode of a MIM capacitor element;

(d) patterning the dielectric layer to leave a dielectric film of the MIM capacitor element, the dielectric film protruding outward from the upper electrode; and

(e) patterning the first metal layer to leave a lower electrode of the MIM capacitor electrode, the lower electrode protruding outward from the dielectric film.

The structure that the dielectric film is disposed projecting outward from the upper electrode by a predetermined distance, can suppress leak current. This predetermined distance confirmed by the experiments made by the present inventor was 0.4 μm although the predetermined distance may change with a drop of particles, process resist residues, etching damages, unexpected conductivity of antireflection film and the like.

### BRIEF DESCRIPTION OF THE DRAWINGS

FIGS. 1A, 1B and 1C are cross sectional views and a graph explaining the experiments made by the present inventor.

FIGS. 2 to 7 are cross sectional views illustrating a method of manufacturing a semiconductor device according to an embodiment.

FIG. 8 is a cross sectional view of a semiconductor device according to a modification of the embodiment.

FIGS. 9A and 9B are equivalent circuits showing application examples of MIM capacitor elements.

FIGS. 10A and 10B are equivalent circuits showing application examples of MIM capacitor elements.

### DESCRIPTION OF THE PREFERRED EMBODIMENTS

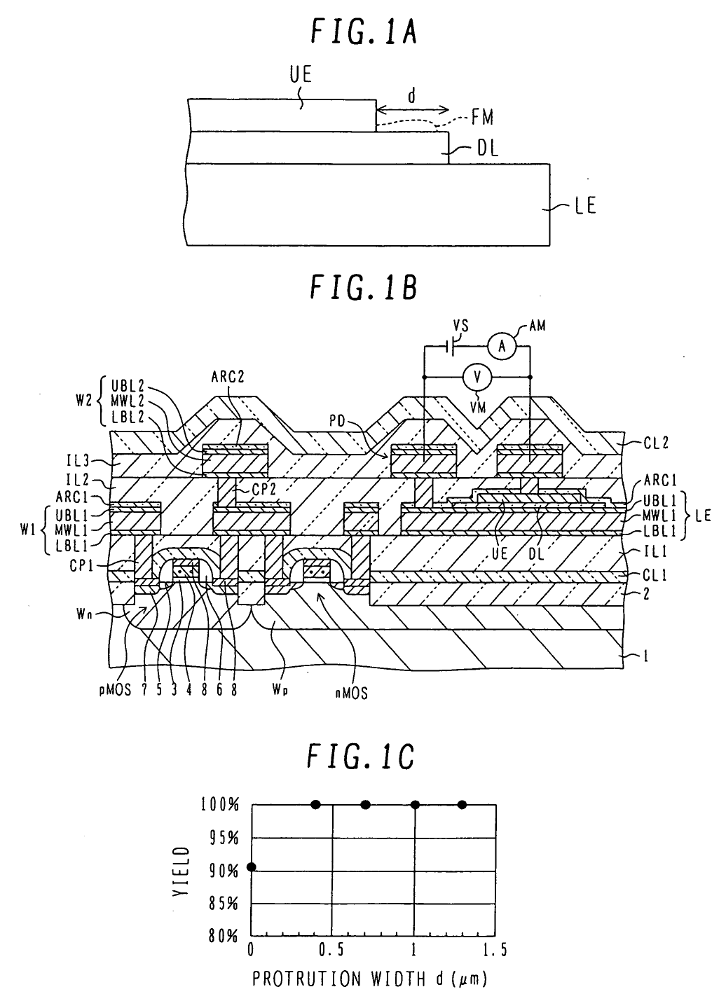

FIG. 1A shows the fundamental structure studied by the present inventor. On a lower electrode LE, a dielectric film DL is formed withdrawing or retracted from the outer periphery of the lower electrode LE, and on the dielectric film DL, an upper electrode UE is formed withdrawing from the outer periphery of the dielectric film DL.

By protruding the dielectric film DL outward from the upper electrode UE by a distance d, the exposed surface of the upper electrode UE is spaced away from the exposed surface of the lower electrode LE, so that even if conductive foreign matter FM is attached or formed, a short circuit is prevented and leak current can be suppressed. The dielectric film DL is patterned to leave it only in an inner area of the MIM lower electrode and remove it from an outer area thereof, so that the optical constants on the wiring layer surface during the lower electrode (and wiring layer) patterning can be made similar to those on the wiring layer surface during the usual wiring layer patterning.

Experiment samples having different protruding distances d of the dielectric film from the upper electrode periphery were formed and manufacture yield regarding leak current were checked.

FIG. 1B shows the structure of an experiment sample. On the surface of a silicon substrate 1, an element isolation region 2 is formed by shallow trench isolation (STI), n-type impurity ions are implanted via a resist mask to form an n-type well Wn, and p-type impurity ions area implanted via another resist mask to form a p-type well WP. A gate insulating film 3 is formed on the surface of an active region defined by the element isolation region through thermal oxidation, and a polysilicon film 4 is deposited and etched into a gate electrode shape.

By using resist masks covering the p-channel well and n-channel well, n-type impurity ions and p-type impurity ions are implanted to form extensions 5 having conductivity types opposite to those of the wells, in the active regions on both sides of the gate electrode 4. An insulating film is deposited and anisotropic etching is performed to form side wall spacers 6 on the gate side walls. By using resist masks, n-type impurity ions and p-type impurity ions are implanted to form high concentration source/drain regions 7 having conductivity types opposite to those of the wells. A cobalt film is deposited and silicide layers 8 are formed on the silicon surface through silicidation. With these processes, n-channel MOS (nMOS) and p-channel MOS (pMOS) transistor structures are formed.

A cover (etch stopper) film CL1 of silicon nitride and a first interlayer insulating film IL1 of silicon oxide are formed covering nMOS and pMOS. Contact holes are formed through the interlayer insulating film IL1 and cover film CL1, and conductive (tungsten) plugs CP1 are buried in the contact holes. On the interlayer insulating film IL1, a lower barrier layer LBL1, a main wiring layer MWL1 and an upper barrier layer UBL1 are formed in this order for a lower electrode LE and wirings W1. The lower barrier layer LBL1 is a lamination of a TiN film having a thickness of 10 nm formed on a Ti film having a thickness of 60 nm, the main wiring layer MWL1 is made of Al (Cu 5%) and has a thickness of 400 nm, and the upper barrier layer UBL1 is a lamination of a TiN layer having a thickness of 70 nm formed on a Ti layer having a thickness of 5 nm. On the upper barrier layer UBL1, a silicon oxide film having a thickness of 30 nm is formed for a dielectric film DL, and on the silicon oxide film, a TiN layer having a thickness of 150 nm is formed for an upper electrode film UE.

By using different resist masks, the upper electrode and dielectric film are etched in a tiered stand shape. 100 chips were formed at protrusion distances of 0 μm, 0.4 μm, 0.7 μm, 1 μm and 1.3 μm of the dielectric film DL from the outer periphery of the upper electrode UE.

After an SiON film having a thickness of 31 nm is formed as an antireflection film ARC, the lower electrode LE and wirings W1 are formed through etching using a resist mask. The lower electrode LE protrudes outward from the dielectric film DL. The MIM capacitor element has the size of an area of 1 mm² and a peripheral length of 400 mm.

An interlayer insulating film IL2 of silicon oxide is deposited and contact holes are formed to bury therein conductive (tungsten) plugs CP2. Formed on the interlayer insulating film IL2 are a lower barrier layer LBL2, a main wiring layer MWL2 and an upper barrier layer UBL2 having the same structure as that of the wiring layer described above. After an antireflection film ARC2 is formed, wirings W2 and a pad PD connected to the conductive plugs CP2 are formed by patterning using a resist mask. After an interlayer insulating film IL3 of silicon oxide is formed, a cover film CL2 of silicon nitride is deposited to a thickness of 500 nm.

A voltage from a d.c. voltage source VS was applied across the upper electrode UE and lower electrode LE, and an applied voltage was measured with a voltmeter VM and a leak current was measured with an ammeter AM. A criterion current was set to 15 pA (0.025 fA/μm² per area and 0.0625 fA/μm² per peripheral length) at an applied voltage of 4 V, and it was judged defective when leak current flows at the criterion current or more.

FIG. 1C is a graph showing the experiment results. At the protrusion width d of 0 μm (without protrusion), the yield was about 91%. It can be considered that defective products have a conductive leak path between the upper and lower electrodes due to a drop of particles, process resist residues, etching damages, unexpected conductivity of antireflection film and the like.

At the protrusion width of 0.4 μm or wider, the yield was 100%. It was confirmed that leak current could be reduced considerably by protruding the dielectric film outward from the upper electrode. Since samples having the protrusion width narrower than 0.4 μm other than 0 μm were not formed, it is indefinite that the yield of 100% is obtained starting at what protrusion width. It is however preferable from the viewpoint of safety to set the protrusion distance to 0.4 μm or longer in order to suppress leak current

In the following, description will be made on a semiconductor device and its manufacture method according to the embodiment.

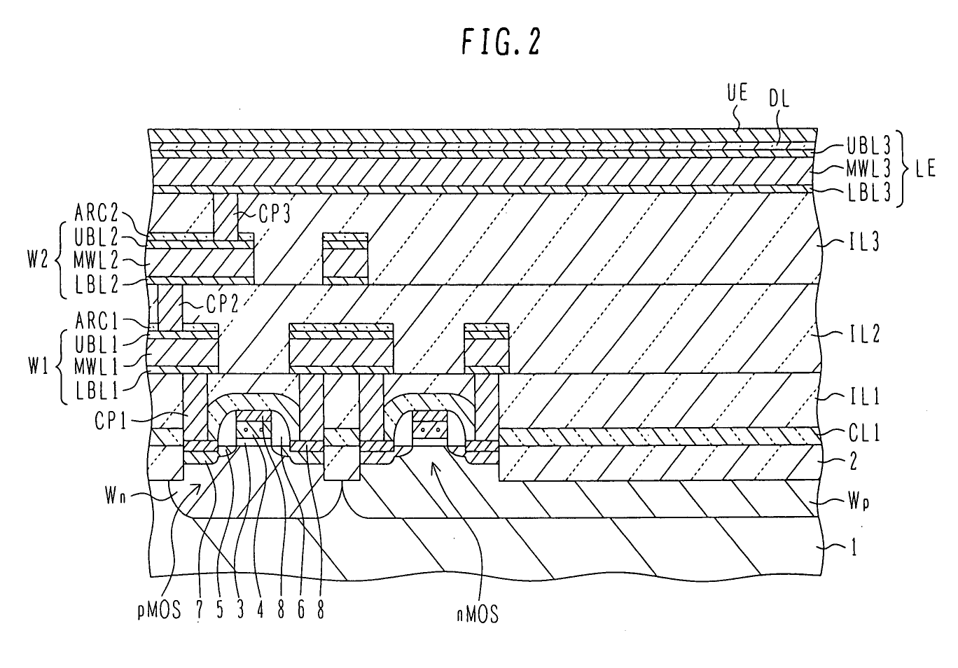

As shown in FIG. 2, an element isolation region 2, an n-well Wn and a p-well Wp are formed in a semiconductor substrate 1, and p- and n-channel MOS transistors PMOS and nMOS are formed in the n- and p-wells Wn and Wp. A cover film CL1 of silicon nitride and a first interlayer insulating film IL1 of silicon oxide are formed covering PMOS and nMOS, and the first interlayer insulating film is planarized by chemical mechanical polishing (CMP). First conductive (tungsten) plugs CP1 are formed extending through the interlayer insulating film IL1 and cover film CL1 and reaching source/drain regions of the transistors.

The processes up to this are the same as the manufacture processes of forming the samples described with reference to FIGS. 1A and 1B. Other processes well-known to semiconductor device manufacture technologies may be used. For example, the element isolation region may be formed by local oxidation of silicon (LOCOS) instead of STI. The materials of the insulating films such as the interlayer insulating film may be other proper materials. A single layer structure may be replaced with a multilayer structure. Although the barrier layer of the conductive tungsten plug is generally made of a TiN layer, it may have a different structure. The conductive plug may be made of polysilicon.

On the first interlayer insulating film IL1, a lower barrier layer LBL1, a main wiring layer MWL1 and an upper barrier layer UBL1 are formed in this order for first wirings W1. The lower barrier layer LBL1 is a lamination of a TiN film having a thickness of 5 to 15 nm formed on a Ti film having a thickness of 50 to 70 nm, the main wiring layer MWL1 is made of Al (Cu 5%) and has a thickness of 300 to 500 nm, and the upper barrier layer UBL1 is a lamination of a TiN layer having a thickness of 50 to 100 nm formed on a Ti layer having a thickness of 3 to 10 nm. On the upper barrier layer UBL1, an antireflection film ARC1 of silicon oxynitride having a thickness of 20 to 40 nm is formed, and on the antireflection film, a resist pattern is formed and the lamination structure is etched to leave first wirings W1. Instead of silicon oxynitride, silicon nitride may be used as the material of the antireflection film. An inverter is therefore formed being constituted of pMOS and nMOS interconnected by the first wirings W1.

A second interlayer insulating film IL2 of silicon oxide is formed covering the first wirings W1 and planarized by CMP. Thereafter, a second conductive plug CP2 interconnecting the first wiring and an upper second wiring is formed. For example, after a TiN layer is formed by sputtering, a blanket W layer is formed by CVD utilizing a WF₆ reduction reaction. An unnecessary metal layer on the interlayer insulating film IL2 is removed by CMP to leave the conductive plug.

With similar processes, second wirings W2, a third conductive plug CP3 and a third interlayer insulating film IL3 are formed. On the third interlayer insulating film IL3, a lower barrier layer LBL3, a main wiring layer MWL3 and an upper barrier layer UBL3 are formed in this order for the lower electrode LE and third wiring W3 of a MIM capacitor element. The lower barrier layer LBL3 is a lamination of a TiN film having a thickness of 5 to 15 nm formed on a Ti film having a thickness of 50 to 70 nm, the main wiring layer MWL1 is made of Al (Cu 5%) and has a thickness of 300 to 500 nm, and the upper barrier layer UBL1 is a lamination of a TiN layer having a thickness of 50 to 100 nm formed on a Ti layer having a thickness of 3 to 10 nm. On the upper barrier layer UBL3, a silicon oxide film having a thickness of 20 to 50 nm is formed for a dielectric film DL, and on the silicon oxide film, a TiN layer having a thickness of 100 to 200 nm is formed for an upper electrode film UE.

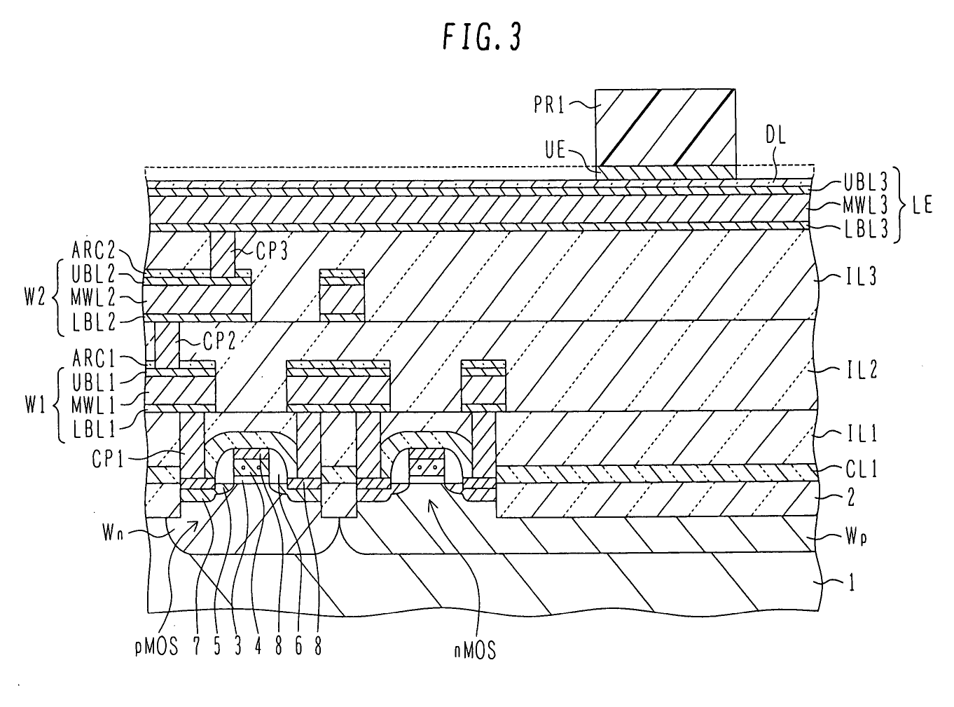

As shown in FIG. 3, on the upper electrode layer, a resist mask PR1 for patterning the upper electrode is formed, and the upper electrode layer is anisotropically etched to leave an upper electrode UE. The resist mask PR1 is thereafter removed.

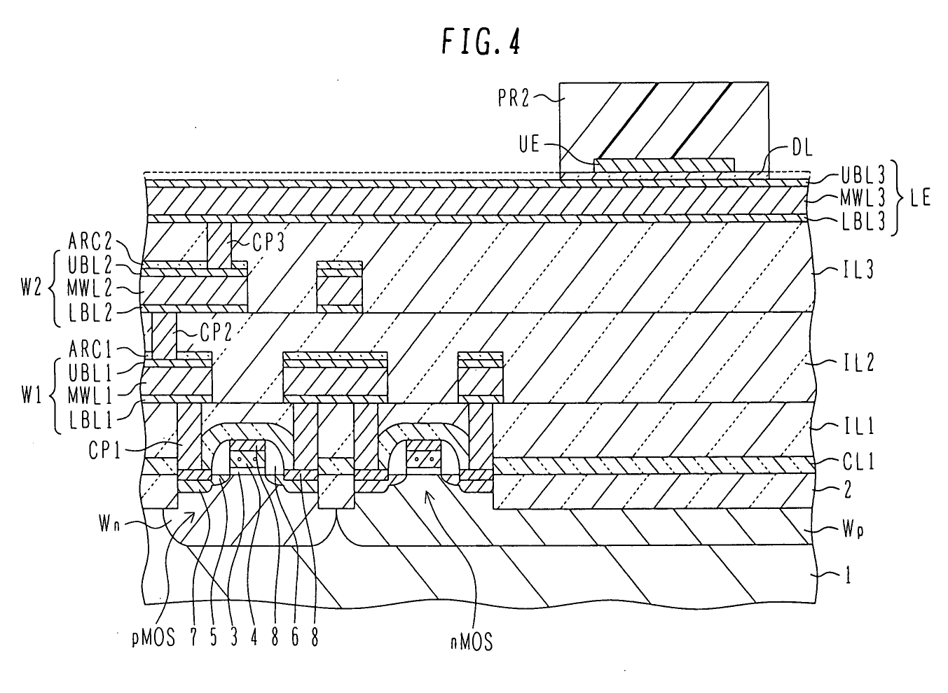

As shown in FIG. 4, a resist mask PR2 having a shape inclusive of the upper electrode UE and the dielectric film DL is anisotropically etched. In this case, the dielectric film DL is protruded from the outer periphery of the upper electrode, preferably by 0.4 μm or wider. The resist mask PR2 is thereafter removed.

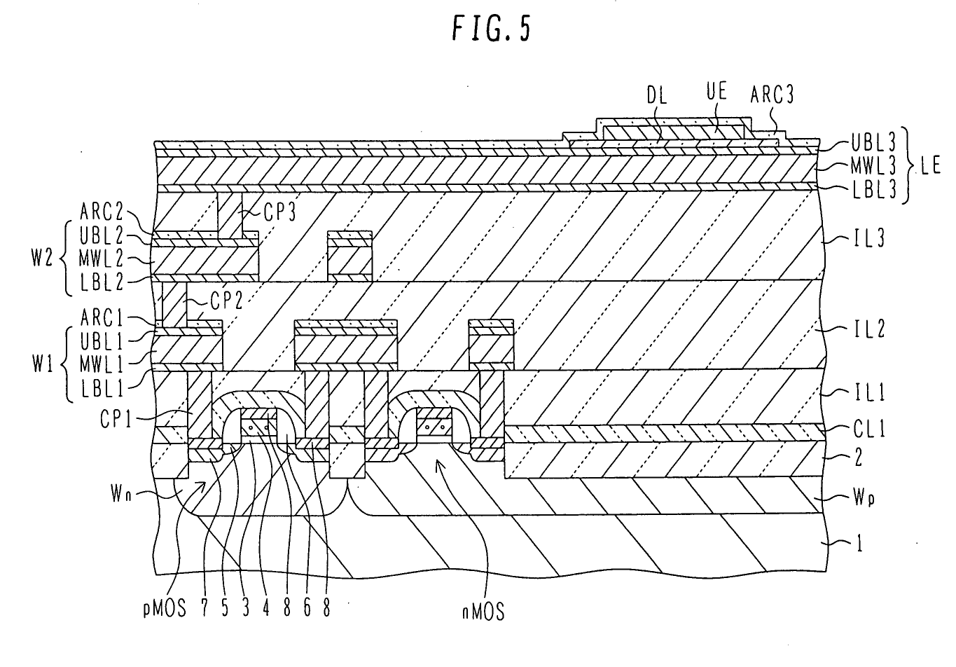

As shown in FIG. 5, an antireflection film ARC3 of silicon oxynitride having a thickness of about 20 to 40 nm is formed on the whole surface of the substrate having the patterned dielectric film DL. Instead of silicon oxynitride, silicon nitride may be used. It is preferable that the Si composition does not become too large as compared to the compositions of oxygen and nitrogen in order not to impart conductivity.

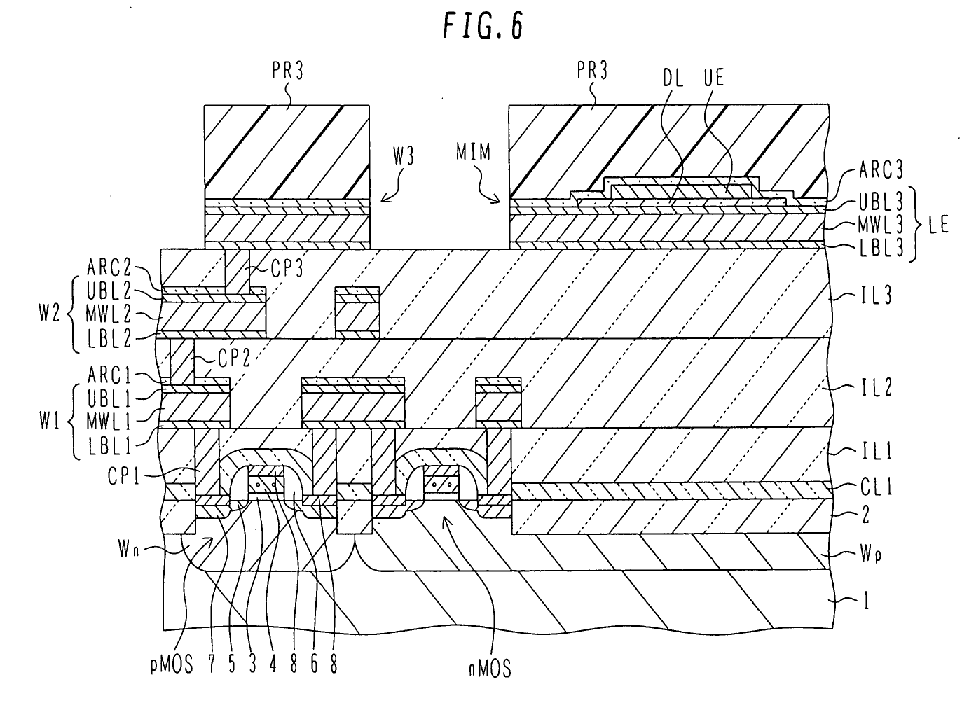

As shown in FIG. 6, a resist mask PR3 having the shapes of the lower electrode LE and the third wiring W3 is formed to anisotropically etch the antireflection film ARC3, upper barrier layer UBL3, Al main wiring layer MWL3 and lower barrier layer LBL3. A capacitor element MIM is therefore patterned having the tiered stand shape of the upper electrode UE, dielectric film DL and lower electrode LE and a wiring W3 having the same structure as that of the lower electrode. The resist mask PR3 is thereafter removed.

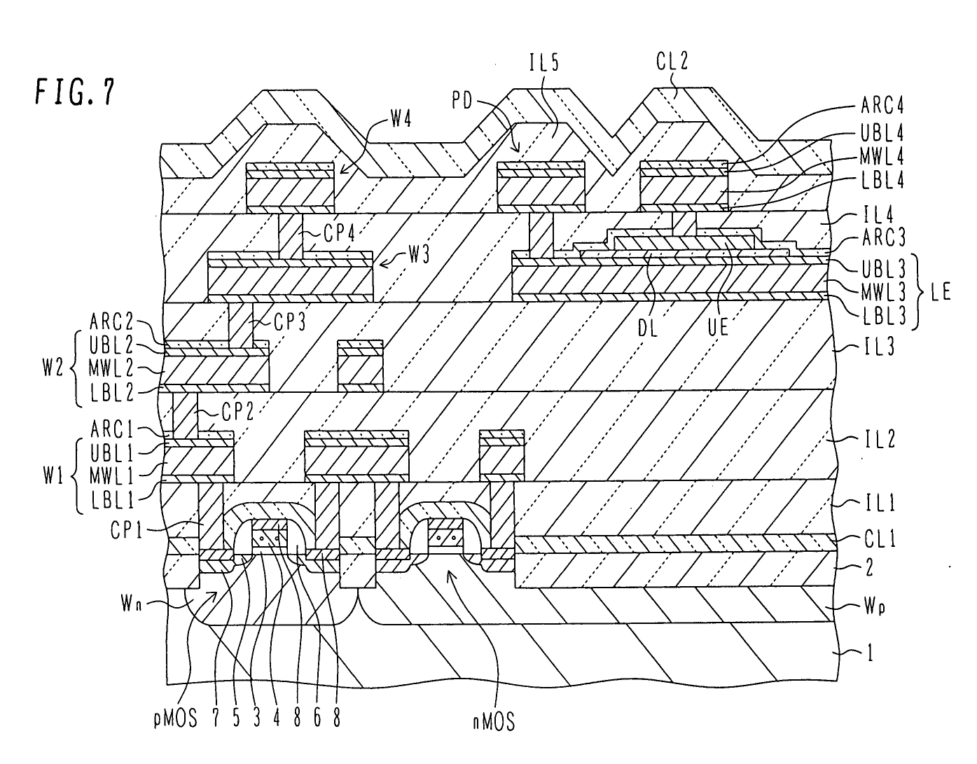

As shown in FIG. 7, a fourth interlayer insulating film IL4 is formed covering the MIM capacitor element and third wiring W3, and planarized. Thereafter, via holes are etched and conductive plugs CP4 are buried in the via holes. Each of these processes is similar to the corresponding one of the processes described above. On the interlayer insulating film IL4, a lower barrier layer LBL4, a main wiring layer MWL4 and an upper barrier layer UBL4 having the same structure as that of the wiring layer described above are formed, and an antireflection film ARC4 is formed and patterned by using a resist mask to form a wiring W4 and a pad PD connected to the conductive plugs CP4. After an interlayer insulating film IL5 of silicon oxide is formed, a cover film CL2 of silicon nitride having a thickness of 400 to 600 nm is formed.

The cover film CL2 and interlayer insulating film IL5 are selectively etched to expose the surface of the pad PD. With theses processes, a semiconductor device is manufactured having a MIM capacitor element and third aluminum wirings formed by partially using common processes, above the two aluminum wiring layers.

In this embodiment, a multilayer wiring structure is made of aluminum wirings. Copper wirings may also be used.

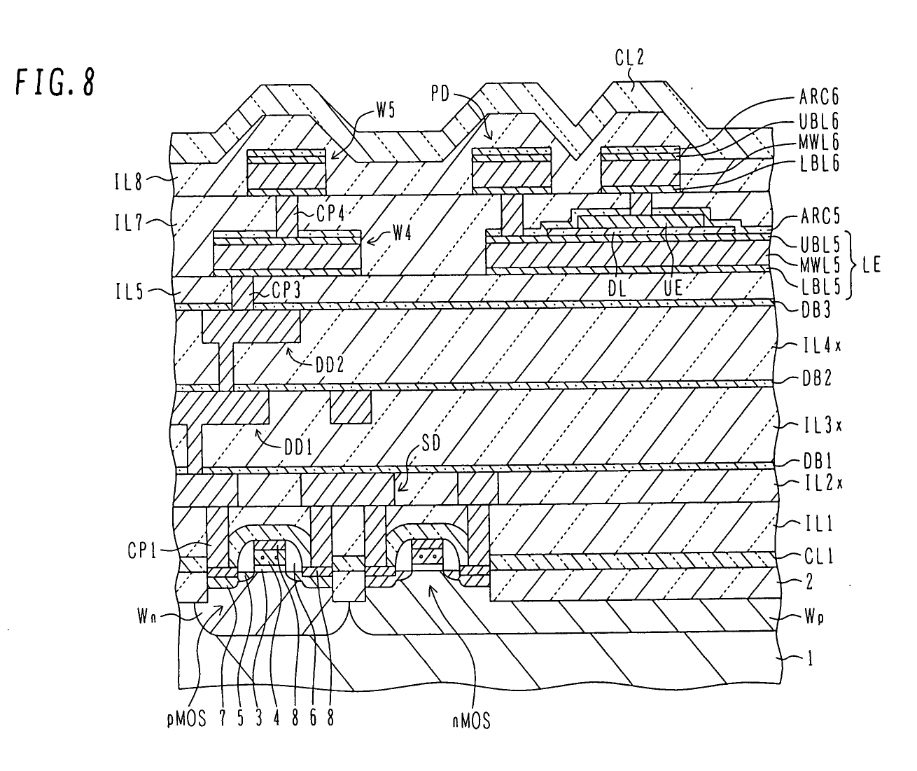

FIG. 8 shows a semiconductor device using copper wirings. An element isolation region 2, an n-well Wn and a p-well Wp are formed in a semiconductor substrate 1, and p- and n-channel MOS transistors pMOS and nMOS are formed in the n- and p-wells Wn and Wp. A cover film CL1 of silicon nitride and a first interlayer insulating film IL1 of silicon oxide are formed covering PMOS and nMOS. First conductive (tungsten) plugs CP1 are formed extending through the interlayer insulating film IL1 and cover film CL1 and reaching source/drain regions of the transistors. The processes up to this are the same as the embodiment manufacture processes described with reference to FIG. 2.

On the first interlayer insulating film IL1, a second interlayer insulating film IL2x of silicon oxide is formed, wiring trenches are formed by etching to expose the conductive plug CP1, and a copper wiring SD of a single damascene is buried in the trench. A copper diffusion preventive film DB1 of silicon nitride or the like is formed on the interlayer insulating film IL2x, covering the copper wiring SD. The copper diffusion preventive film has also a function of an etch stopper. Instead of silicon nitride, silicon carbide may be used.

On the copper diffusion preventive film DB1, an interlayer insulating film IL3x of silicon oxide or the like is formed, a wiring trench and a via hole extending from the bottom of the trench and reaching the lower wiring are formed by etching or the like. A copper diffusion barrier layer and a copper seed layer are formed by sputtering, and a copper layer is formed thereon by plating. An unnecessary metal layer on the interlayer insulating film IL3x is removed by CMP to leave a copper wiring DD1 of a dual damascene in the trench and via hole.

By using similar processes, a dual damascene copper wiring DD2 buried in the copper diffusion preventive film DB2 and interlayer insulating film IL4x is formed, and a copper diffusion preventive film DB3 is formed covering the dual damascene copper wiring DD2.

On the copper diffusion preventive film DB3, an interlayer insulating film IL5 of silicon oxide or the like is formed, a via hole is formed through the interlayer insulating film IL5 and copper diffusion preventive film DB3, reaching the lower wiring DD2, and a conductive plug CP3 of tungsten or the like is buried in the via hole. Thereafter, by using processes similar to those of the above-described embodiment, an aluminum wiring layer including a lower barrier layer LBL5, a main wiring layer MWL5 and an upper barrier layer UBL5, a dielectric film DL and an upper electrode Ti layer are laminated, and after the upper electrode UE and dielectric film DL are formed by etching, an antireflection film ARC5 is formed. The antireflection film ARC5 and aluminum wiring layer are patterned to form a fourth wiring W4 covered with the antireflection film ARC5 and a lower electrode LE formed by the same lamination as that of the wiring layer. A MIM capacitor element of the tiered stand shape covered with the antireflection film ARC5 is therefore formed having a lamination of the lower electrode LE, dielectric film DL and upper electrode UE.

Thereafter, an interlayer insulating film IL7 is formed on the whole substrate surface, via holes are formed and conductive plugs CP4 are buried in the via holes. A lower barrier layer LBL6, a main wiring layer MWL6, an upper barrier layer UBL6 and an antireflection film ARC6 are laminated and patterned to form wirings W5 and a pad PD. An interlayer insulating film IL8 and a cover film CL2 are formed to complete the structure shown in FIG. 8. The cover film CL2 and interlayer insulating film IL8 are selectively etched to expose the surface of the pad PD.

Although the second and third wiring layers have the dual damascene structure, they may have the single damascene structure forming a via conductor and a trench conductor by different processes. The whole of or a portion of the interlayer insulating film may be made of a low dielectric constant organic insulating film such as a fluorine-containing silicon oxide film, a porous silicon oxide film and SiLK®.

Application examples of high precision MIM capacitor elements will be described.

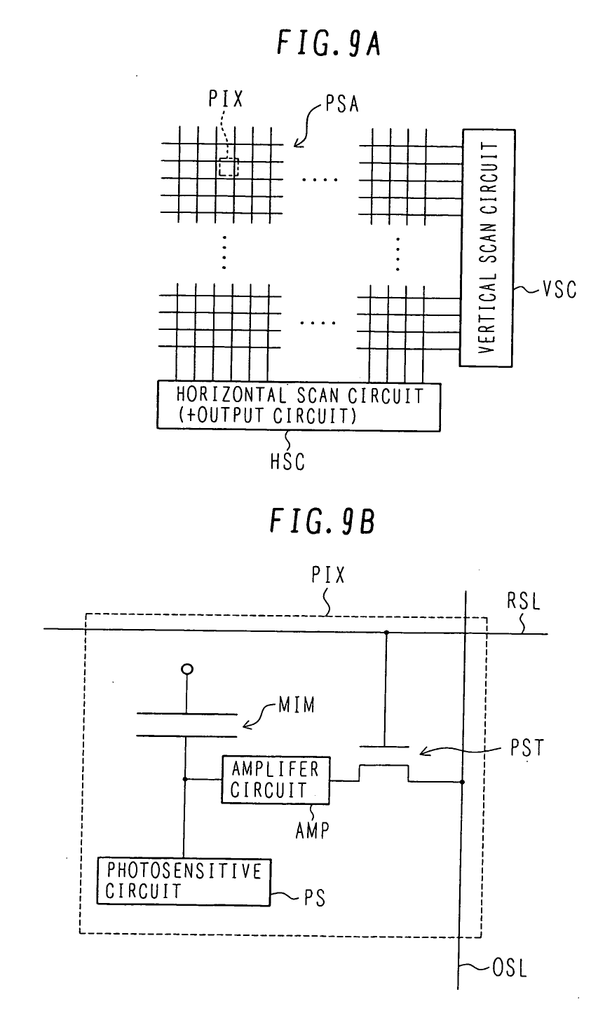

FIGS. 9A and 9B show an application example of MIM capacitor elements of a CMOS image sensor. As shown in FIG. 9A, a number of pixels PIX are disposed in a photosensitive area PSA in a matrix shape, and scan lines are disposed in horizontal and vertical directions, extending from a vertical scan circuit VSC and a horizontal scan circuit HSC serving also as an output circuit.

As shown in FIG. 9B, in each pixel PIX, a MIM capacitor element MIM and an amplifier circuit AMP are connected to an output terminal of a photoreception unit including a photodiode and a charge detection circuit, and an output terminal of the amplifier circuit AMP is connected to an output signal line OSL via a pixel select transistor PST. A row select line RSL is connected to the gate of the pixel select transistor PST. One pixel is selected by the outputs from the vertical scan circuit VSC and horizontal scan circuit HSC, and when the pixel select transistor PST turns on, a voltage corresponding to charges accumulated in the capacitor element MIM is amplified by the amplifier circuit AMP and supplied to the output signal line OSL. Since the pixel signal is generated in accordance with the accumulation voltage of the capacitor element MIM, the capacitor element MIM is required to have high precision. By using a high precision MIM capacitor element, image signals of a uniform quality and high precision can be obtained.

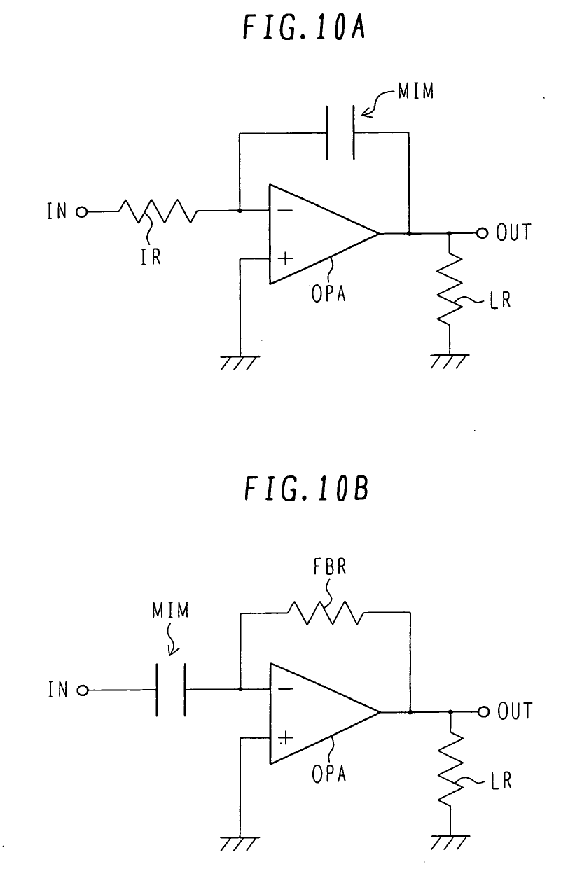

FIGS. 10A and 10B show application examples of an integrating circuit and a differentiating circuit of an analog circuit. As shown in FIG. 10A, an integrating circuit has a capacitor element MIM connected across input/output terminals of an operational amplifier OPA, an input resistor connected across an input terminal IN and the input terminal of the operational amplifier OPA, and a load resistor LR connected between ground and an output terminal OUT connected to the output terminal of the operational amplifier.

As shown in FIG. 10B, a differentiating circuit has a capacitor element MIM connected between an input terminal IN and an input terminal of an operational amplifier OPA, a feedback resistor FBR connected between the input/output terminals of the operational amplifier, and a load resistor LR connected between ground and the output terminal OUT connected to the output terminal of the operational amplifier.

In this analog circuit, a precision of the circuit is governed by the capacitor element MIM. By using the embodiment MIM capacitor element, high precision can be guaranteed.

The present invention has been described in connection with the preferred embodiments. The invention is not limited only to the above embodiments. It will be apparent to those skilled in the art that other various modifications, improvements, combinations, and the like can be made.

What are claimed are:

1. A semiconductor device comprising:
a semiconductor substrate;
a plurality of semiconductor elements formed in said semiconductor substrate;
a metal wiring made of a first metal layer and formed above said semiconductor substrate;
a lower electrode made of said first metal layer and formed above said semiconductor substrate;
a dielectric film formed on said lower electrode in a shape withdrawing from a periphery of said lower electrode; and
an upper electrode formed on said dielectric film in a shape withdrawing from a periphery of said dielectric film,
wherein said lower electrode, said dielectric film and said upper electrode form a MIM capacitor element.

2. The semiconductor device according to claim 1, wherein the periphery of said upper electrode is set remotely from the periphery of said dielectric film by 0.4 μm or longer.

3. The semiconductor device according to claim 1, wherein said first metal layer is made of a lamination of a Ti layer, a TiN layer, an Al layer or an Al alloy layer, a Ti layer and a TiN layer stacked from a bottom in this order, and said upper electrode is made of a TiN layer.

4. The semiconductor device according to claim 1, further comprising:
an insulating antireflection film covering an upper surface of said metal wiring, an upper surface and side wall of said upper electrode, an upper surface and side wall of said dielectric film in an area not covered with said upper electrode, and an upper surface of said lower electrode in an area not covered with said dielectric film; and
an interlayer insulating film covering said antireflection film.

5. The semiconductor device according to claim 4, further comprising:
a plurality of via conductors extending through said interlayer insulating film and said antireflection film and reaching said metal wiring, said upper electrode and said lower electrode; and
a plurality of upper layer wirings formed on said interlayer insulating film and connected to said via conductors.

6. The semiconductor device according to any one of claims 1 to 5, wherein said plurality of semiconductor elements contain a light reception element and a detection circuit, and said MIM capacitor element is connected to said light reception element.

7. The semiconductor device according to any one of claims 1 to 5, wherein said plurality of semiconductor elements contain an analog circuit including an operational amplifier, and said MIM capacitor element is connected to said operational amplifier.

8. A semiconductor device manufacture method comprising the steps of:
(a) forming a plurality of semiconductor elements in a semiconductor substrate;
(b) laminating a first metal layer, a dielectric film and a second metal layer, in this order, above said semiconductor substrate;
(c) patterning said second metal layer to leave an upper electrode of a MIM capacitor element;
(d) patterning said dielectric layer to leave a dielectric film of the MIM capacitor element, the dielectric film protruding outward from said upper electrode; and
(e) patterning said first metal layer to leave a wiring and a lower electrode of the MIM capacitor electrode, the lower electrode protruding outward from said dielectric film.

9. The semiconductor device manufacturing method according to claim 8, wherein said step (d) forms the dielectric film protruding from a periphery of said second metal layer by at least 0.4 μm.

10. The semiconductor device manufacturing method according to claim 8, wherein said step (b) laminates a plurality of layers as said first metal layer.

11. The semiconductor device manufacturing method according to claim 10, wherein said plurality of layers include a Ti layer, a TiN layer, a main conductor layer, and another TiN layer.

12. The semiconductor device manufacturing method according to claim 11, wherein said second metal layer includes a TiN layer.

13. The semiconductor device manufacturing method according to any one of claims 8 to 12, wherein said steps (d) and (e) perform patterning by etching using resist mask.

14. The semiconductor device manufacture method according to any one of claims 8 to 12, further comprising the step of:
(f) forming an insulating antireflection film on a whole surface of said semiconductor substrate, between said steps (d) and (e).

15. The semiconductor device manufacture method according to claim 14, further comprising the steps of:
(g) forming an interlayer insulating film on the whole surface of said semiconductor substrate after said step (e);
(h) forming via holes extending through said interlayer insulating film and said antireflection film and reaching said wiring, said upper electrode and said lower electrode; and
(i) burying conductors in said via holes.
